(19) United States
(12) Patent Application Publication
(10) Pub. No.: US 2026/0238212 A1
(43) Pub. Date: Aug. 13, 2026

(54) VOLTAGE DRIVER

(71) Applicant: EMEMORY TECHNOLOGY INC., HSINCHU (TW)

(72) Inventors: HSU-YA LIU, HSINCHU COUNTY (TW); CHENG-DA HUANG, HSINCHU COUNTY (TW)

(21) Appl. No.: 19/534,780

(22) Filed: Feb. 10, 2026

Related U.S. Application Data
(60) Provisional application No. 63/757,372, filed on Feb. 12, 2025.

(51) Int. Cl. H03K 19/0185; G11C 17/16; G11C 17/18; H03K 17/687

(52) U.S. Cl. CPC H03K 19/018507; G11C 17/16; G11C 17/18; H03K 17/6872

(57) ABSTRACT

A voltage driver includes a first P-type transistor, a second P-type transistor, a first N-type transistor, and a second N-type transistor. The first P-type transistor has a first terminal for receiving a pumped voltage, a second terminal, and a control terminal for receiving a first control signal. The second P-type transistor has a first terminal coupled to the second terminal of the first P-type transistor, a second terminal for outputting a driving signal, and a control terminal for receiving a power voltage. The first N-type transistor has a first terminal coupled to the second terminal of the second P-type transistor, a second terminal, and a control terminal for receiving the power voltage. The second N-type transistor has a first terminal coupled to the second terminal of the first N-type transistor, a second terminal for receiving a reference voltage, and a control terminal for receiving a second control signal.

### CROSS REFERENCE

This application claims the benefit of prior-filed U.S. provisional application No. 63/757,372, filed on Feb. 12, 2025, which is incorporated by reference in its entirety.

### TECHNICAL FIELD

The present disclosure relates to a voltage driver, and more particularly, to a voltage driver that is durable for high voltage operations.

### DISCUSSION OF THE BACKGROUND

In response to the need for low power consumption in electronic devices, integrated circuits (IC) have been re-designed to operate in low voltage environments. While lower voltages are beneficial for reducing power consumption, there are still situations where greater voltages are necessary. For example, non-volatile memory may require a high voltage for performing program operation, and such high voltage is typically provided by a level shifter and a voltage driver.

However, to design a level shifter and a voltage driver that work in the low voltage environment can be challenging. For example, special care may need to be taken to ensure that the transistors used in the circuits can operate within their safe operating areas (SOA). Therefore, how to design an efficient high voltage output circuit that can operate in the low voltage environment has become an issue to be solved.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a voltage driver. The voltage driver includes a first P-type transistor, a second P-type transistor, a first N-type transistor, and a second N-type transistor. The first P-type transistor has a first terminal for receiving a pumped voltage, a second terminal, and a control terminal for receiving a first control signal. The second P-type transistor has a first terminal coupled to the second terminal of the first P-type transistor, a second terminal for outputting a driving signal, and a control terminal for receiving a power voltage. The first N-type transistor has a first terminal coupled to the second terminal of the second P-type transistor, a second terminal, and a control terminal for receiving the power voltage. The second N-type transistor has a first terminal coupled to the second terminal of the first N-type transistor, a second terminal for receiving a reference voltage, and a control terminal for receiving a second control signal. The pumped voltage is higher than the power voltage, and the power voltage is higher than the reference voltage. The first control signal and the second control signal are in phase, the first control signal is switched between a first high voltage and a first low voltage that are higher than or equal to the power voltage, and the second control signal is switched between a second high voltage and a second low voltage that are both lower than or equal to the power voltage.

Another aspect of the present disclosure provides a memory peripheral circuit for providing a driving voltage to program a non-volatile memory cell. The memory peripheral circuit includes a level shifter and a voltage driver. The level shifter generates a first control signal and a second control signal according to an input signal. The voltage driver includes a first P-type transistor, a second P-type transistor, a first N-type transistor, and a second N-type transistor. The first P-type transistor has a first terminal for receiving a pumped voltage, a second terminal, and a control terminal for receiving the first control signal. The second P-type transistor has a first terminal coupled to the second terminal of the first P-type transistor, a second terminal for outputting a driving signal, and a control terminal for receiving a power voltage. The first N-type transistor has a first terminal coupled to the second terminal of the second P-type transistor, a second terminal, and a control terminal for receiving the power voltage. The second N-type transistor has a first terminal coupled to the second terminal of the first N-type transistor, a second terminal for receiving a reference voltage, and a control terminal for receiving the second control signal. The pumped voltage is higher than the power voltage, and the power voltage is higher than the reference voltage. The first control signal and the second control signal are in phase, the first control signal is switched between a first high voltage and a first low voltage that are higher than or equal to the power voltage, and the second control signal is switched between a second high voltage and a second low voltage that are both lower than or equal to the power voltage.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures.

FIG. 1 shows a memory peripheral circuit according to one comparative embodiment of the present disclosure.

FIG. 2 shows a memory peripheral circuit according to one embodiment of the present disclosure.

FIG. 3 shows an application scenario of the memory peripheral circuit in FIG. 2 when the input signal is at the system voltage according to one embodiment of the present disclosure.

FIG. 4 shows another application scenario of the memory peripheral circuit in FIG. 2 when the input signal is at the power voltage according to one embodiment of the present disclosure.

FIG. 5 shows a layout of the wells of the P-type transistors and the N-type transistors according to one embodiment of the present disclosure.

FIG. 6 shows a memory peripheral circuit according to another embodiment of the present disclosure.

FIG. 7 shows an application scenario of the memory peripheral circuit in FIG. 6 when the input signal is at the system voltage according to one embodiment of the present disclosure.

FIG. 8 shows another application scenario of the memory peripheral circuit in FIG. 6 when the input signal is at the power voltage according to one embodiment of the present disclosure.

### DETAILED DESCRIPTION

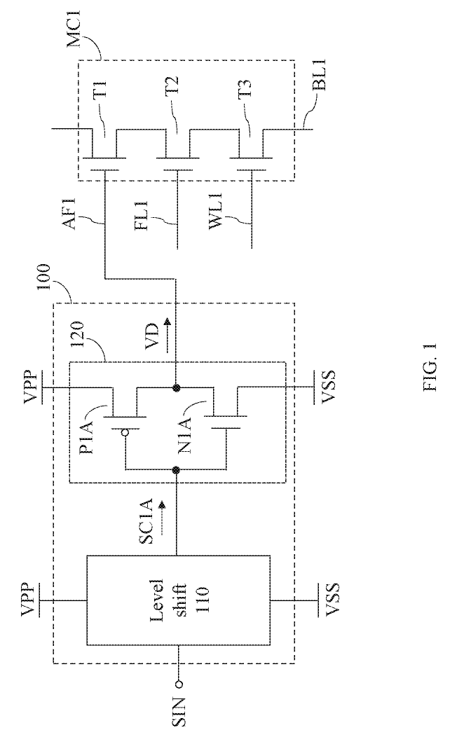

FIG. 1 shows a memory peripheral circuit 100 according to one comparative embodiment of the present disclosure. The memory peripheral circuit 100 includes a level shifter 110 and a voltage driver 120. The memory peripheral circuit 100 can provide a driving voltage VD for programing a non-volatile memory cell MC1.

In the present embodiment, the non-volatile memory cell MC1 includes an anti-fuse transistor T1, a following transistor T2, and a select transistor T3. The anti-fuse transistor T1 has a first terminal, a second terminal, and a gate terminal. The gate terminal includes an oxide layer with a breakdown voltage greater than 5V (e.g., 5.25V), and is coupled to an anti-fuse control line AF1. The following transistor T2 has a first terminal coupled to the second terminal of the anti-fuse transistor T1, a second terminal, and a control terminal coupled to a following gate line FL1. The select transistor T3 has a first terminal coupled to the second terminal of the following transistor T2, a second terminal coupled to a bit line BL1, and a control terminal coupled to a word line WL1.

When the non-volatile memory cell MC1 can be selected in the program mode to perform the program operation, a voltage at the bit line BL1 is at a low voltage level, and a voltage at the word line WL1 and a voltage at the following gate line FL1 are raised to high voltage levels so that the select transistor T3 and the following transistor T2 can be turned on. Furthermore, during the program operation of the non-volatile memory cell MC1, the memory peripheral circuit 100 can provide a driving voltage VD1 at a high voltage level to the anti-fuse control line AF1 so the anti-fuse transistor T1 will receive a large voltage between its second terminal and its gate terminal. As a result, the gate oxide of the gate terminal of the anti-fuse transistor T1 can be ruptured, thereby forming a low resistance path between its gate terminal and second terminal. Consequently, the non-volatile memory cell MC1 can be programmed.

In some embodiments, during the program operation, the voltage at the following gate line FL1 can be higher than the voltage at the word line WL1 so that the following transistor T2 can help to reduce the cross voltage applied to the select transistor T3, thereby reducing the gate-induced-drain-leakage (GIDL) and prevent the punch current. However, in some embodiments, the following transistor T2 may be omitted according to the system needs, and the first terminal of the select transistor T3 may be coupled to the second terminal of the anti-fuse transistor T1 directly.

In the embodiment shown in FIG. 1, to provide the driving voltage VD that can rupture the anti-fuse transistor T1 during the program operation, the memory peripheral circuit 100 employs the level shifter 110 to generate a control signal SC1A according to an input signal SIN. In some embodiments, the input signal SIN is switched within a first voltage domain, such as between a system voltage VSS and a power voltage VDD, and the control signal SC1A can be switched within a second voltage domain, such as between the system voltage VSS and a pumped voltage VPP. In other words, the level shifter 110 may generate the control signal SC1A by shifting the voltage level of the input signal SIN when the input signal SIN is at the power voltage VDD. In some embodiments, the pumped voltage VPP can be higher than the power voltage VDD, and the power voltage VDD can be higher than the system voltage VSS. For example, the system voltage VSS can be the ground voltage, the power voltage VDD can be 1.8V, and the pumped voltage VPP can be 5.25V. However, the present disclosure is not limited thereto.

The memory peripheral circuit 100 further employs the voltage driver 120 as a buffer to output the driving voltage VD according to the control signal SC1A so as to ensure the driving ability of the driving voltage VD.

The voltage driver 120 includes a P-type transistor (e.g., a PMOS) P1A, and an N-type transistor (e.g., a NMOS) N1A. The P-type transistor P1A has a first terminal for receiving the pumped voltage VPP, a second terminal, and a control terminal for receiving the control signal SC1A. The N-type transistor N1A has a first terminal coupled to the second terminal of the P-type transistor P1A, a second terminal for receiving the system voltage VSS, and a control terminal coupled to the control terminal of the P-type transistor P1A.

In some embodiments, the P-type transistor P1A and the N-type transistor N1A can be implemented with low voltage devices or medium voltage devices that have breakdown voltage lower than the pumped voltage VPP (e.g., the pumped voltage VPP can be 5.25V, and the breakdown voltage of the P-type transistor P1A and the N-type transistor N1A can be 5V). In such case, when the control signal SC1A is at the pumped voltage VPP, the N-type transistor N1A is turned on and the P-type transistor P1A is turned off, and thus, the driving voltage VD is pulled down to the system voltage VSS. As a result, the drain-to-source voltage of the P-type transistor P1A is about the pumped voltage VPP, which may lead to the breakdown of the P-type transistor P1A. Also, when the control signal SC1A is at the system voltage VSS, the P-type transistor P1A is turned on and the N-type transistor N1A is turned off, and thus, the driving voltage VD is pulled up to the pumped voltage VPP. As a result, the drain-to-source voltage of the N-type transistor N1A is about the pumped voltage VPP, which may lead to the breakdown of the N-type transistor N1A.

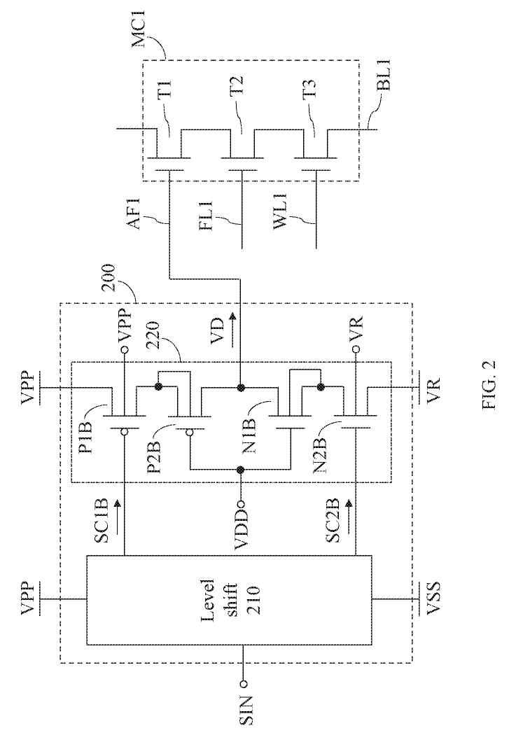

To protect the transistors in the voltage driver 120 from breaking down, a cascode structure may be adopted. FIG. 2 shows a memory peripheral circuit 200 according to one embodiment of the present disclosure.

The memory peripheral circuit 200 includes a level shifter 210 and a voltage driver 220. The level shifter 210 can generate control signals SC1B and SC2B according to the input signal SIN. In some embodiments, the control signal SC1B and the control signal SC2B are in phase. The control signal SC1B is switched between a first high voltage VH1 and a first low voltage VL1 that are higher than or equal to the power voltage VDD, and the control signal SC2B is switched between a second high voltage VH2 and a second low voltage VL2 that are both lower than or equal to the power voltage VDD. For example, the pumped voltage VPP can be 5.25V, the power voltage VDD can be 1.8V, and the system voltage VSS can be the ground voltage. In such case, the high voltage VH1 can be same as the pumped voltage VPP, and the low voltage VL1 can be higher than or equal to the power voltage VDD. For example, the low voltage VL1 can be 2V. In addition, the high voltage VH2 can be same as the power voltage VDD and low voltage VL2 can be same as the system voltage VSS.

The voltage driver 220 includes P-type transistors P1B, P2B and N-type transistors N1B, N2B. The P-type transistor P1B has a first terminal for receiving the pumped voltage VPP, a second terminal, and a control terminal for receiving the control signal SC1B. The P-type transistor P2B has a first terminal coupled to the second terminal of the P-type transistor P1B, a second terminal for outputting the driving voltage VD, and a control terminal for receiving the power voltage VDD. The N-type transistor N1B has a first terminal coupled to the second terminal of the P-type transistor P2B, a second terminal, and a control terminal for receiving the power voltage VDD. The N-type transistor N2B has a first terminal coupled to the second terminal of the N-type transistor N1B, a second terminal for receiving a reference voltage VR, and a control terminal for receiving the control signal SC2B. In the present embodiment the reference voltage VR can be same as the system voltage VSS.

Furthermore, a body terminal of the P-type transistor P1B receives the pumped voltage VPP, and the body terminal of the second P-type transistor P2B is coupled to the first terminal of the P-type transistor P2B. In addition, a body terminal of the N-type transistor N1B is coupled to the second terminal of the N-type transistor N1B, and a body terminal of the N-type transistor N2B receives the reference voltage VR.

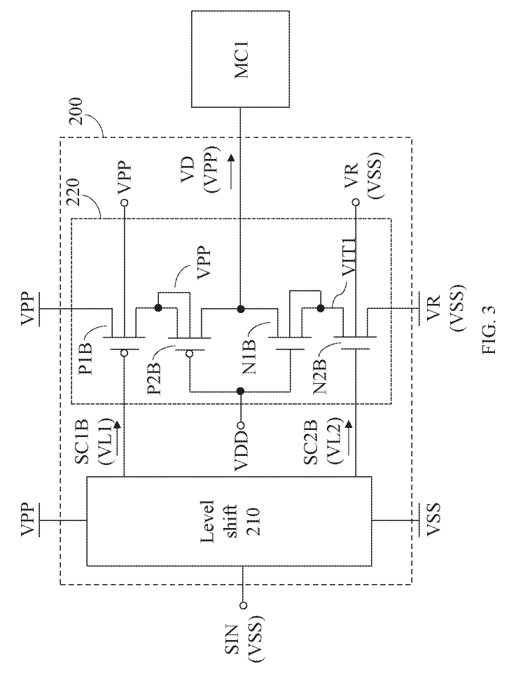

In such case, the P-type transistors P1B, P2B and the N-type transistors N1B, N2B can be protected from breaking down caused by excessive voltage across their terminals. FIG. 3 shows an application scenario of the memory peripheral circuit 200 when the input signal SIN is at the system voltage VSS according to one embodiment of the present disclosure. In such case, the control signals SC1B and SC2B are at the low voltages VL1 (e.g., 2V) and VL2 (e.g., system voltage VSS), so the P-type transistors P1B and P2B are turned on while the N-type transistors N1B and N2B are turned off. Consequently, the pumped voltage VPP (e.g., 5.25V) is outputted as the driving voltage VD. As shown in FIG. 3, the gate-to-drain voltages, the gate-to-source voltages, the drain-to-source voltages, the drain-to-body voltages, and the body-to-source voltages of the P-type transistors P1B and P2B can be kept smaller than the breakdown voltage of the P-type transistors P1B and P2B (e.g., the breakdown voltage of the P-type transistors P1B and P2B can be 5V), and thus, the P-type transistors P1B and P2B can be protected from breaking down.

Furthermore, in FIG. 3, due to the cascode structure, the voltage at the second terminal of the N-type transistor N1B can be lowered, so as to protect the N-type transistors N1B and N2B from breaking down. In some embodiments, the voltage at the second terminal of the N-type transistor N1B can be at an intermediate voltage VIT1 between the power voltage VDD and the system voltage VSS (e.g., 1.58V). In such case, the gate-to-drain voltages, the gate-to-source voltages, the drain-to-source voltages, the drain-to-body voltages, and the body-to-source voltages can also be kept smaller than the breakdown voltage of the N-type transistors N1B and N2B (e.g., the breakdown voltage of the N-type transistors N1B and N2B can be same as the breakdown voltage of the P-type transistors P1B and P2B at 5V), and thus, the N-type transistors N1B and N2B can be protected from breaking down.

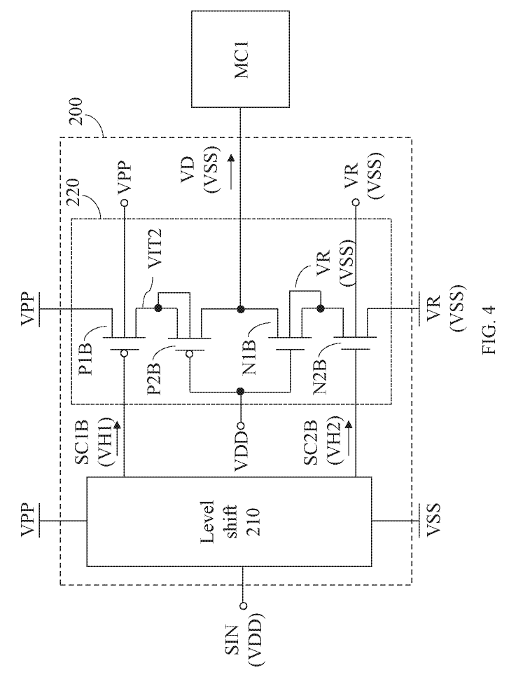

FIG. 4 shows another application scenario of the memory peripheral circuit 200 when the input signal SIN is at the power voltage VDD according to one embodiment of the present disclosure. In such case, the control signals SC1B and SC2B are at the high voltages VH1 (e.g., the pumped voltage VPP) and VH2 (e.g., the power voltage VDD), so the P-type transistors P1B and P2B are turned off while the N-type transistors N1B and N2B are turned on, and the reference voltage VR (in this case, the reference voltage VR is same as the system voltage VSS) is outputted as the driving voltage VD. As shown in FIG. 4, the gate-to-drain voltages, the gate-to-source voltages, the drain-to-source voltages, the drain-to-body voltages, and the body-to-source voltages of the N-type transistors N1B and N2B can be kept smaller than the breakdown voltage, and thus, the N-type transistors N1B and N2B can be protected from breaking down.

Furthermore, in FIG. 4, due to the cascode structure, the voltage at the second terminal of the P-type transistor P1B can be lowered, so as to protect the P-type transistors P1B and P2B from breaking down. In some embodiments, the voltage at the second terminal of the P-type transistor P1B can be about at an intermediate voltage VIT2 between the pumped voltage VPP and the power voltage VDD (e.g. 2V). In such case, the gate-to-drain voltages, the gate-to-source voltages, the drain-to-source voltages, the drain-to-body voltages, and the body-to-source voltages can also be kept smaller than the breakdown voltage, and thus, the P-type transistors P1B and P2B can be protected from breaking down.

In the present embodiment, the body terminals of the P-type transistors P1B, P2B and the body terminals of the N-type transistors N1B, N2B are all coupled to different voltages so that the drain-to-body voltages, and the body-to-source voltages received by the P-type transistors P1B, P2B and the N-type transistors N1B, N2B can be controlled within their breakdown voltages. However, such configuration also demands the P-type transistors P1B, P2B and the N-type transistors N1B, N2B to be formed in different wells and may increase the area of the voltage driver 220.

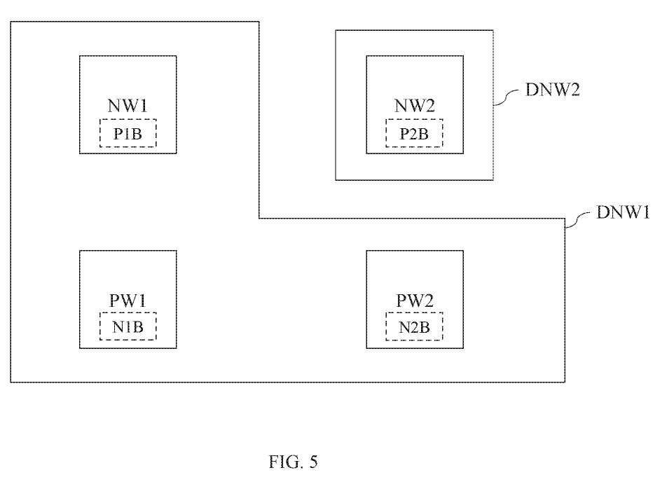

FIG. 5 shows a layout of the wells of the P-type transistors P1B, P2B and the N-type transistors N1B, N2B according to one embodiment of the present disclosure. As shown in FIG. 5, the voltage driver 220 includes deep N-wells DNW1 and DNW2. In such case, the P-type transistor P1B can be formed in an N-well NW1 disposed in the deep N-well DNW1, and the P-type transistor P2B can be formed in an N-well NW2 disposed in the deep N-well DNW2. Also, the N-type transistor N1B can be formed in a P-well PW1 disposed in the deep N-well DNW1, and the N-type transistor N2B can be formed in a P-well PW2 disposed in the deep N-well DNW1. Since the P-type transistors P1B, P2B and the N-type transistors N1B, N2B need to be formed in different wells, the voltage driver 220 may require larger area for implementation.

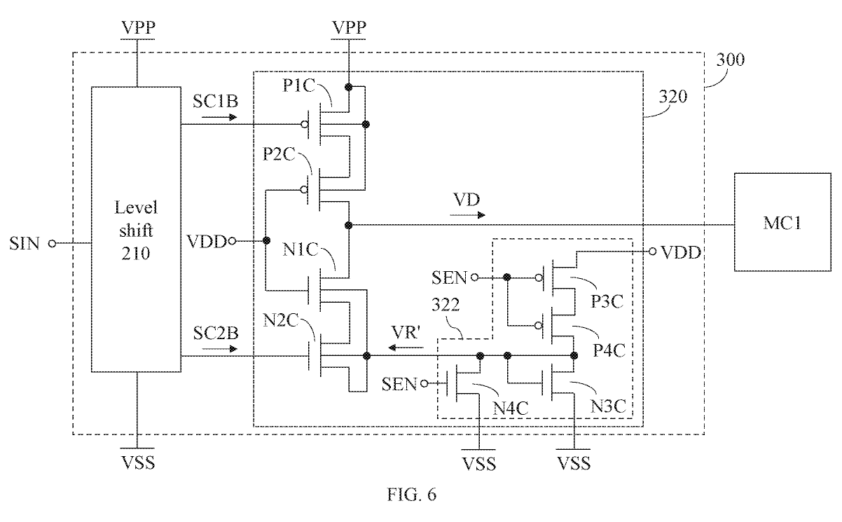

FIG. 6 shows a memory peripheral circuit 300 according to another embodiment of the present disclosure. The memory peripheral circuit 300 is different from the memory peripheral circuit 200 in that the body terminals of the P-type transistors P1C and P2C can receive the pumped voltage VPP, and the body terminals of the N-type transistors N1C and N2C can receive the reference voltage VR' that is higher than the system voltage VSS and lower than the power voltage VDD. Furthermore, a difference between the pumped voltage VPP and the reference voltage VR' is smaller than the breakdown voltage of the N-type transistor N1C and the P-type transistor P2C. In such case, the P-type transistors P1C, P2C and the N-type transistors N1C, N2C can be protected from breaking down caused by excessive voltage across their terminals. In some embodiments, the system voltage VSS can be 0V, and the reference voltage VR' can be 0.5V. In other words, the voltage driver 320 can adopt the reference voltage VR' that is slightly higher than the system voltage VSS so as to protect the P-type transistor P2C and the N-type transistor N2C.

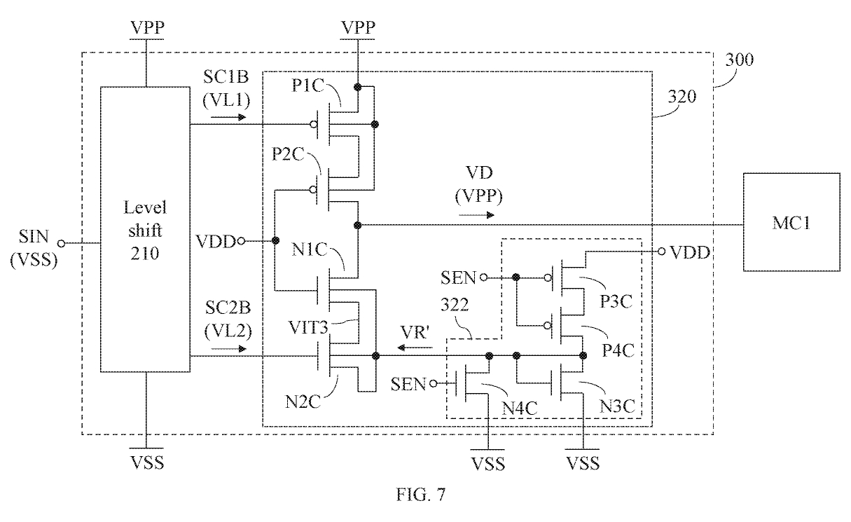

FIG. 7 shows an application scenario of the memory peripheral circuit 300 when the input signal SIN is at the system voltage VSS according to one embodiment of the present disclosure. In such case, the control signals SC1B and SC2B are at the low voltages VL1 (e.g., 2V) and VL2 (e.g., system voltage VSS), so the P-type transistors P1C and P2C are turned on while the N-type transistors N1C and N2C are turned off. Consequently, the pumped voltage VPP (e.g., 5.25V) is outputted as the driving voltage VD. As shown in FIG. 7, the gate-to-drain voltages, the gate-to-source voltages, the drain-to-source voltages, the drain-to-body voltages, and the body-to-source voltages of the P-type transistors P1C and P2C can be kept smaller than the breakdown voltage of the P-type transistors P1C and P2C (e.g., the breakdown voltage of the P-type transistors P1C and P2C can be 5V), and thus, the P-type transistors P1C and P2C can be protected from breaking down.

Furthermore, in FIG. 7, due to the cascode structure, the voltage at the second terminal of the N-type transistor N1C can be lowered, so as to protect the N-type transistors N1C and N2C from breaking down. In some embodiments, the voltage at the second terminal of the N-type transistor N1C can be at an intermediate voltage VIT3 between the power voltage VDD and the system voltage VSS (e.g., 1.58V). In addition, since the difference between the reference voltage VR' and the pumped voltage VPP can be smaller than the breakdown voltage of the N-type transistor N1C, the gate-to-drain voltages, the gate-to-source voltages, the drain-to-source voltages, the drain-to-body voltages, and the body-to-source voltages can both be kept smaller than the breakdown voltage of the N-type transistors N1C and N2C, and thus, the N-type transistors N1C and N2C can be protected from breaking down.

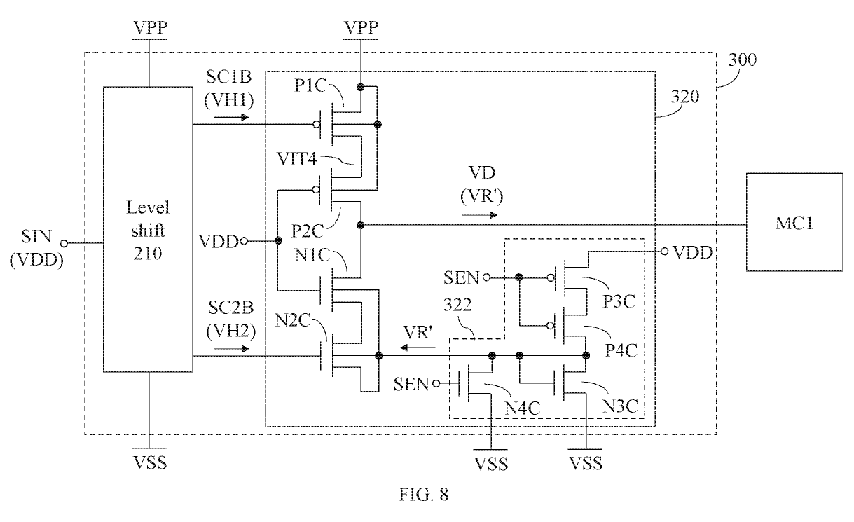

FIG. 8 shows another application scenario of the memory peripheral circuit 300 when the input signal SIN is at the power voltage VDD according to one embodiment of the present disclosure. In such case, the control signals SC1B and SC2B are at the high voltages VH1 (e.g., the pumped voltage VPP) and VH2 (e.g., the power voltage VDD), so the P-type transistors P1C and P2C are turned off while the N-type transistors N1C and N2C are turned on, and the reference voltage VR' (in this case, the reference voltage VR' is higher than the system voltage VSS) is outputted as the driving voltage VD.As shown in FIG. 8, the gate-to-drain voltages, the gate-to-source voltages, the drain-to-source voltages, the drain-to-body voltages, and the body-to-source voltages of the N-type transistors N1C and N2C can be kept smaller than the breakdown voltage, and thus, the N-type transistors N1C and N2C can be protected from breaking down.

Furthermore, in FIG. 8, due to the cascode structure, the voltage at the second terminal of the P-type transistor P1C can be lowered, so as to protect the P-type transistors P1C and P2C from breaking down. In some embodiments, the voltage at the second terminal of the P-type transistor P1C can be at an intermediate voltage VIT4 between the pumped voltage VPP and the power voltage VDD (e.g. 2V). In addition, since the difference between the reference voltage VR' and the pumped voltage VPP can be smaller than the breakdown voltage of the P-type transistor P2C, the gate-to-drain voltages, the gate-to-source voltages, the drain-to-source voltages, the drain-to-body voltages, and the body-to-source voltages can also be kept smaller than the breakdown voltage, and thus, the P-type transistors P1C and P2C can be protected from breaking down.

With the configuration of the voltage driver 320, the P-type transistors P1C and P2C can be formed in a same N-well, the N-type transistors N1C and N2C can be formed in a same P-well with the N-well and the P-well disposed in a same deep N-well, and thus, the area required by the voltage driver 320 can be reduced.

In the present embodiment, the voltage driver 320 may further include a reference voltage generator 322 for generating the reference voltage VR'. As shown in FIG. 8, the reference voltage generator 322 includes P-type transistors P3C, P4C and N-type transistors N3C, N4C. The P-type transistor P3C has a first terminal for receiving the power voltage VDD, a second terminal, and a control terminal for receiving an enable signal SEN. The P-type transistor P4C has a first terminal coupled to the second terminal of the P-type transistor P3C, a second terminal, and a control terminal for receiving the enable signal SEN. The N-type transistor N3C has a first terminal coupled to the second terminal of the P-type transistor P4C, a second terminal for receiving the system voltage VSS, and a control terminal coupled to the first terminal of the N-type transistor N3C. The N-type transistor N4C has a first terminal coupled to the second terminal of the P-type transistor P4C, a second terminal for receiving the system voltage VSS, and a control terminal for receiving the enable signal SEN.

In some embodiments, the enable signal SEN can be at a high level (e.g., the power voltage VDD) when the non-volatile memory cell MC1 is not in a program mode, and the N-type transistors N4C can be turned on to pull down the reference voltage VR' to the system voltage VSS. Also, the enable signal SEN can be at a low level (e.g., the system voltage VSS) when the non-volatile memory cell MC1 enters the program mode. In such case, as the enable signal SEN is changed to the low level, the P-type transistors P3C and P4C can be turned on, creating a current path from the first terminal of the P-type transistor P3C to the second terminal of the P-type transistor P4C. The N-type transistor N3C acts as a voltage clamper because it is configured in a diode-connected structure. Specifically, since the N-type transistor N3C is diode-connected, it begins to conduct current to the system voltage (VSS) once the reference voltage VR' reaches the threshold voltage of N-type transistor N3C. This mechanism effectively clamps the reference voltage VR', preventing it from rising significantly higher. Consequently, the reference voltage VR' finally stabilizes at approximately the threshold voltage of the N-type transistor N3C. In some embodiments, the power voltage VDD may be 1.8V, the threshold voltage of the N-type transistor N3C may be 0.5V, and the reference voltage VR' can be 0.5V. However, the present disclosure is not limited thereto. In some embodiments, the reference voltage generator 322 may include different number of P-type transistors for generating the reference voltage VR' required by the system.

In summary the voltage drivers and the memory peripheral circuits provided by the embodiments of the present disclosure may adopt the cascode structure to protect the transistors therein from breaking down caused by excessive voltage across their terminals. Furthermore, the voltage drivers and the memory peripheral circuits provided by the embodiments of the present disclosure may further adjust the connection of the body terminals of the transistors therein or to adjust the reference voltages provided to the N-type transistors so as to further ensure the transistors can work in their safety operation area (SOA).

What is claimed is:

1. A voltage driver comprising:
a first P-type transistor having a first terminal configured to receive a pumped voltage, a second terminal, and a control terminal configured to receive a first control signal;
a second P-type transistor having a first terminal coupled to the second terminal of the first P-type transistor, a second terminal configured to output a driving signal, and a control terminal configured to receive a power voltage;
a first N-type transistor having a first terminal coupled to the second terminal of the second P-type transistor, a second terminal, and a control terminal configured to receive the power voltage; and
a second N-type transistor having a first terminal coupled to the second terminal of the first N-type transistor, a second terminal configured to receive a reference voltage, and a control terminal configured to receive a second control signal;
wherein:
the pumped voltage is higher than the power voltage, and the power voltage is higher than the reference voltage; and
the first control signal and the second control signal are in phase, the first control signal is switched between a first high voltage and a first low voltage that are higher than or equal to the power voltage, and the second control signal is switched between a second high voltage and a second low voltage that are both lower than or equal to the power voltage.

2. The voltage driver of claim 1, wherein:
a body terminal of the first P-type transistor is configured to receive the pumped voltage; and
a body terminal of the second N-type transistor is configured to receive the reference voltage.

3. The voltage driver of claim 2, wherein:
a body terminal of the second P-type transistor is configured to receive the pumped voltage;
a body terminal of the first N-type transistor is configured to receive the reference voltage; and
the reference voltage is higher than a system voltage, and a difference between the pumped voltage and the reference voltage is smaller than a breakdown voltage of the first N-type transistor.

4. The voltage driver of claim 3, further comprising a reference voltage generator configured to generate the reference voltage, and the reference voltage generator comprises:
a third P-type transistor having a first terminal configured to receive the power voltage, a second terminal, and a control terminal configured to receive an enable signal;
a fourth P-type transistor having a first terminal coupled to the second terminal of the third P-type transistor, a second terminal configured to output the reference voltage when the enable signal is at a low level, and a control terminal configured to receive the enable signal;
a third N-type transistor having a first terminal coupled to the second terminal of the fourth P-type transistor, a second terminal configured to receive a system voltage, and a control terminal coupled to the first terminal of the third N-type transistor; and
a fourth N-type transistor having a first terminal coupled to the second terminal of the fourth P-type transistor, a second terminal configured to receive the system voltage, and a control terminal configured to receive the enable signal.

5. The voltage driver of claim 3, wherein:
the first high voltage is equal to the pumped voltage, the first low voltage is higher than or equal to the power voltage and is lower than the first high voltage; and
the second high voltage is equal to the power voltage, the second low voltage is equal to the system voltage.

6. The voltage driver of claim 2, wherein:
a body terminal of the second P-type transistor is coupled to the first terminal of the second P-type transistor; and
a body terminal of the first N-type transistor is coupled to the second terminal of the first N-type transistor.

7. The voltage driver of claim 6, further comprising a first deep N-well and a second deep N-well, wherein:
the first P-type transistor is formed in a first N-well disposed in the first deep N-well;
the second P-type transistor is formed in a second N-well disposed in the second deep N-well;
the first N-type transistor is formed in a first P-well disposed in the first deep N-well; and
the second N-type transistor is formed in a second P-well disposed in the first deep N-well.

8. The voltage driver of claim 6, wherein:
the first high voltage is equal to the pumped voltage, the first low voltage is higher than or equal to the power voltage and is lower than the first high voltage;
the second high voltage is equal to the power voltage, the second low voltage is equal to a system voltage; and
the reference voltage is equal to the system voltage.

9. A memory peripheral circuit for providing a driving voltage to program a non-volatile memory cell, the memory peripheral circuit comprising:
a level shifter configured to generate a first control signal and a second control signal according to an input signal; and
a voltage driver comprises:
a first P-type transistor having a first terminal configured to receive a pumped voltage, a second terminal, and a control terminal configured to receive the first control signal;
a second P-type transistor having a first terminal coupled to the second terminal of the first P-type transistor, a second terminal configured to output a driving signal, and a control terminal configured to receive a power voltage;
a first N-type transistor having a first terminal coupled to the second terminal of the second P-type transistor, a second terminal, and a control terminal configured to receive the power voltage; and
a second N-type transistor having a first terminal coupled to the second terminal of the first N-type transistor, a second terminal configured to receive a reference voltage, and a control terminal configured to receive the second control signal;
wherein:
the pumped voltage is higher than the power voltage, and the power voltage is higher than the reference voltage; and
the first control signal and the second control signal are in phase, the first control signal is switched between a first high voltage and a first low voltage that are higher than or equal to the power voltage, and the second control signal is switched between a second high voltage and a second low voltage that are both lower than or equal to the power voltage.

10. The memory peripheral circuit of claim 9, wherein:
a body terminal of the first P-type transistor is configured to receive the pumped voltage; and
a body terminal of the second N-type transistor is configured to receive the reference voltage.

11. The memory peripheral circuit of claim 10, wherein:
a body terminal of the second P-type transistor is configured to receive the pumped voltage;
a body terminal of the first N-type transistor is configured to receive the reference voltage; and
the reference voltage is higher than a system voltage, and a difference between the pumped voltage and the reference voltage is smaller than a breakdown voltage of the first N-type transistor.

12. The memory peripheral circuit of claim 11, wherein the voltage driver further comprises a reference voltage generator configured to generate the reference voltage, and the reference voltage generator comprises:
a third P-type transistor having a first terminal configured to receive the power voltage, a second terminal, and a control terminal configured to receive an enable signal;
a fourth P-type transistor having a first terminal coupled to the second terminal of the third P-type transistor, a second terminal configured to output the reference voltage when the enable signal is at a low level, and a control terminal configured to receive the enable signal;
a third N-type transistor having a first terminal coupled to the second terminal of the fourth P-type transistor, a second terminal configured to receive a system voltage, and a control terminal coupled to the first terminal of the third N-type transistor; and
a fourth N-type transistor having a first terminal coupled to the second terminal of the fourth P-type transistor, a second terminal configured to receive the system voltage, and a control terminal configured to receive the enable signal;
wherein the enable signal is at the low level when the non-volatile memory cell is in a program mode, and the enable signal is at a high level when the non-volatile memory cell is not in a program mode.

13. The memory peripheral circuit of claim 11, wherein:
the first high voltage is equal to the pumped voltage, the first low voltage is higher than or equal to the power voltage and is lower than the first high voltage; and
the second high voltage is equal to the power voltage, the second low voltage is equal to the system voltage.

14. The memory peripheral circuit of claim 9, wherein:
a body terminal of the second P-type transistor is coupled to the first terminal of the second P-type transistor; and
a body terminal of the first N-type transistor is coupled to the second terminal of the first N-type transistor.

15. The memory peripheral circuit of claim 14, wherein the voltage driver further comprises a first deep N-well and a second deep N-well, wherein:
the first P-type transistor is formed in a first N-well disposed in the first deep N-well;
the second P-type transistor is formed in a second N-well disposed in the second deep N-well;
the first N-type transistor is formed in a first P-well disposed in the first deep N-well; and
the second N-type transistor is formed in a second P-well disposed in the first deep N-well.

16. The memory peripheral circuit of claim 15, wherein:
the first high voltage is equal to the pumped voltage, the first low voltage is higher than or equal to the power voltage and is lower than the first high voltage;
the second high voltage is equal to the power voltage, the second low voltage is equal to a system voltage; and
the reference voltage is equal to the system voltage.
